(19) United States
(12) Patent Application Publication
(10) Pub. No.: US 2021/0233750 A1
(43) Pub. Date: Jul. 29, 2021

(54) PLASMA PROCESSING APPARATUS

(71) Applicant: Tokyo Electron Limited, Tokyo (JP)

(72) Inventor: Hachishiro IIZUKA, Yamanashi (JP)

(21) Appl. No.: 17/054,896

(22) PCT Filed: May 17, 2019
(86) PCT No.: PCT/JP2019/019801

§ 371 Date: Nov. 12, 2020

(30) Foreign Application Priority Data
May 23, 2018 (JP) 2018-098952

(51) Int. Cl. H01J 37/32; C23C 16/505; C23C 16/458

(52) U.S. Cl. CPC H01J 37/32724; H01J 37/32082; H01J 2237/20235; C23C 16/4586; C23C 16/505

(57) ABSTRACT

A plasma processing apparatus includes: a support provided with a wiring used for a plasma processing and configured to support a stage on which a workpiece serving as a plasma processing target is disposed; a filter that is connected to an end portion of the wiring, and attenuates noise propagated through the wiring; and an elevating unit that moves the support and the filter up and down integrally.

### TECHNICAL FIELD

The present disclosure relates to a plasma processing apparatus.

### BACKGROUND

Patent Document 1 discloses a plasma processing apparatus including an elevating mechanism that moves a stage on which a processing target such as a semiconductor wafer is disposed up and down. For example, the plasma processing apparatus lowers the stage to a processing target transfer position when carrying in/out the processing target, and raises the stage to a processing position suitable for a plasma processing when performing a plasma processing.

### PRIOR ART DOCUMENT

Patent Document
Patent Document 1: Japanese Patent Laid-Open Publication No. 2006-045635

### SUMMARY OF THE INVENTION

### Problem to be Solved

The present disclosure provides a technology capable of suppressing noise propagated through a wiring even when a stage is moved up and down.

### Means to Solve the Problem

A plasma processing apparatus according to an aspect of the present disclosure includes a support, a filter, and an elevating unit. The support supports a stage on which workpiece serving as a plasma processing target is disposed, and is provided with a wiring used for a plasma processing. The filter is connected to an end portion of the wiring, and attenuates noise propagated through the wiring. The elevating unit moves the support and the filter up and down integrally.

### Effect of the Invention

According to the present disclosure, it is possible to suppress the noise propagated through the wiring even when the stage is moved up and down.

### BRIEF DESCRIPTION OF THE DRAWINGS

FIG. 1 is a cross-sectional view illustrating an example of a schematic configuration of a plasma processing apparatus according to an embodiment.

FIG. 2 is a cross-sectional view illustrating an example of a configuration of a stage and a support according to the embodiment.

FIG. 3 is an enlarged view of a vicinity of the stage according to the embodiment.

FIG. 4 is a top view illustrating an example of the configuration of the support according to the embodiment.

FIG. 5 is a bottom view illustrating an example of the configuration of the support according to the embodiment.

FIG. 6A is a view illustrating an example of an arrangement of a wiring in a through hole according to the embodiment.

FIG. 6B is a view illustrating an example of an arrangement of a wiring in a through hole according to the embodiment.

FIG. 6C is a view illustrating an example of an arrangement of a wiring in a through hole according to the embodiment.

FIG. 6D is a view illustrating an example of an arrangement of a wiring in a through hole according to the embodiment.

### DETAILED DESCRIPTION TO EXECUTE THE INVENTION

Hereinafter, embodiments of the plasma processing apparatus disclosed herein will be described in detail with reference to drawings. The plasma processing apparatus disclosed herein is not limited to the exemplary embodiments.

The plasma processing apparatus may generate radio-frequency noise as a plasma is generated, and the noise may be propagated along the wiring provided in the stage. In the plasma processing apparatus, a filter that attenuates the noise is provided at the end portion of the wiring, in order to suppress the noise from being propagated to the outside. For example, in the plasma processing apparatus, a heater or a power supply wiring to the heater is provided in the stage. In the power supply wiring, noise is generated due to the radio-frequency power applied during a plasma processing. As a result, in the plasma processing apparatus, the filter that attenuates the noise is provided at the end portion of the power supply wiring.

However, in the plasma processing apparatus, when the stage is moved up and down, the wiring is moved due to the moving up and down and the impedance of the wiring is changed, and thus, the noise through the wiring may not be sufficiently suppressed by the filter. Therefore, it is expected to suppress the noise through the wiring even when the stage is moved up and down.

[Configuration of Plasma Processing Apparatus]

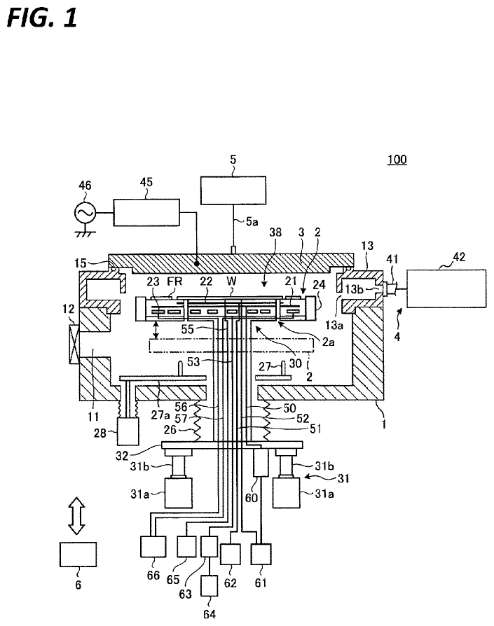

Next, descriptions will be made on a configuration of the plasma processing apparatus according to the embodiment. In the following, a plasma processing apparatus that performs film formation on a semiconductor wafer (hereinafter, referred to as a “wafer”) as a workpiece serving as a plasma processing target by a plasma processing will be described as an example. FIG. 1 is a cross-sectional view illustrating an example of a schematic configuration of the plasma processing apparatus according to the embodiment. A plasma processing apparatus 100 includes a processing container 1, a stage 2, an upper electrode 3, an exhaust unit 4, a gas supply mechanism 5, and a controller 6.

The processing container 1 is made of a metal such as aluminum, and has a substantially cylindrical shape.

A carry-in/out port 11 configured to carry in or carry out a wafer W is formed in a side wall of the processing container 1. The carrying-in/out port 11 is opened/closed by a gate valve 12. An annular exhaust duct 13 which has a rectangular cross-sectional shape is provided on a body of the processing container 1. A slit 13a is formed along an inner peripheral surface in the exhaust duct 13. An exhaust port 13b is formed in an outer wall of the exhaust duct 13. The upper electrode 3 is provided on an upper surface of the exhaust duct 13 so as to close an upper opening of the processing container 1. A space between the exhaust duct 13 and the upper electrode 3 is hermetically sealed with a seal 15.

The stage 2 horizontally supports the wafer W serving as a plasma processing target. The stage 2 is formed in a disc shape having a size corresponding to the wafer W. The stage 2 is supported by the support 30. In the stage 2, for example, a heater 21, or an electrode 22 is embedded, and a fiber thermometer (not illustrated) for control of the heater 21 is provided. Further, the stage 2 includes an ejection port (not illustrated) configured to eject a heat transfer gas on the upper surface. Further, the stage 2 includes a coolant flow path 23 therein.

The support 30 is provided with various wirings. For example, the support 30 is provided with a wiring 50 connected to the heater 21, a wiring 51 connected to the electrode 22, and a wiring 52 connected to the fiber thermometer, respectively. Further, the support 30 is provided with a wiring 53 that supplies a radio-frequency power to the stage 2. Further, the support 30 is provided with a pipe 55 that supplies a heat transfer gas or two pipes 56 and 57 for coolant circulation.

The wiring 50 includes a filter 60 at the terminal in order to suppress the noise from being propagated to the outside. The filter 60 is connected to a heater power source 61. The wiring 51 is connected to a DC power source 62. The wiring 52 is connected to the heater power source 61. The wiring 53 is connected with a first radio-frequency power source 64 via a matcher 63. The pipe 55 is connected to a gas supply source 65 that supplies a heat transfer gas to an ejection port (not illustrated). The pipes 56 and 57 are connected to a coolant unit 66. Details of the stage 2 will be described later.

The heater power source 61 supplies power to the heater 21 via the filter 60 and the wiring 50. The heater 21 is supplied with power from the heater power source 61 via the filter 60 to generate heat, and heats the placing surface of the stage 2, so as to raise the wafer W to a predetermined process temperature. A temperature signal of the fiber thermometer is input to the heater power source 61 from the wiring 52. The fiber thermometer is made of a dielectric material, and may limit the propagation of the radio-frequency noise to be small. The heater power source 61 controls the power supplied to the heater 21 according to the temperature signal of the fiber thermometer. Therefore, the wafer W is controlled to a predetermined temperature.

The DC power source 62 applies a predetermined DC voltage to the electrode 22 via the wiring 51. The electrode 22 adsorbs the wafer W by the Coulomb force generated by applying the DC voltage.

The first radio-frequency power source 64 applies a radio-frequency power having a predetermined frequency to the stage 2 via the matcher 63 and the wiring 53 for drawing plasma ions. For example, the first radio-frequency power source 64 applies a radio-frequency power of 13.56 MHz to the stage 2 for drawing ions. In this manner, the stage 2 also functions as a lower electrode. The matcher 63 includes a variable capacitor and an impedance control circuit, and is configured to be capable of controlling at least one of capacitance and impedance. The matcher 63 matches the load impedance with the internal impedance of the first radio-frequency power source 64.

The gas supply source 65 supplies a heat transfer gas to the upper surface of the stage 2 via the pipe 55. The coolant unit 66 is, for example, a chiller unit. The coolant unit 66 is configured to be capable of controlling the temperature of a coolant, and supplies the coolant having a predetermined temperature to the pipe 56. The coolant flow path 23 is supplied with the coolant from the pipe 56. The coolant supplied to the coolant flow path 23 returns to the coolant unit 66 via the pipe 57. The coolant unit 66 controls the temperature of the stage 2 by circulating the coolant in the coolant flow path 23 via the pipes 56 and 57.

The upper electrode 3 is disposed above the stage 2 to face the stage 2. When the plasma processing is performed, a radio-frequency power having a predetermined frequency is applied to the upper electrode 3. For example, the upper electrode 3 is connected to a second radio-frequency power source 46 via a matcher 45. The matcher 45 includes a variable capacitor and an impedance control circuit, and is configured to control at least one of capacitance and impedance. The matcher 45 matches the load impedance with the internal impedance of the second radio-frequency power source 46. The second radio-frequency power source 46 applies power having a predetermined frequency to the upper electrode 3 for plasma generation. For example, the second radio-frequency power source 46 applies a radio-frequency power of 13.56 MHz to the upper electrode 3.

The upper electrode 3 is connected to the gas supply mechanism 5 via a gas pipe 5a. The gas supply mechanism 5 is connected to various gas supply sources of various gases used for the plasma processing via gas supply lines (not illustrated), respectively. Each of the gas supply lines is appropriately branched corresponding to the process of the plasma processing, and is provided with an opening/closing valve and a flow rate controller. The gas supply mechanism 5 is configured to control the flow rate of the various gases by controlling the opening/closing valve or the flow rate controller provided in each of the gas supply lines. The gas supply mechanism 5 supplies the various gases used for the plasma processing to the upper electrode 3.

The upper electrode 3 includes a gas flow path inside thereof, and supplies the various gases supplied from the gas supply mechanism 5 into the processing container 1. That is, the upper electrode 3 also functions as a gas supply that supplies the various gases.

The stage 2 is provided with a cover member 24 made of ceramics such as alumina so as to cover the outer peripheral area of the upper surface, and the side surface. The stage 2 is supported by the support 30, and an elevating unit 31 that moves the stage 2 up and down is provided on the bottom surface of the support 30.

The support 30 penetrates a hole formed in the bottom wall of the processing container 1 and extends downward from the processing container 1, and is provided with a flange 32 that extends outward at the lower end. The elevating unit 31 is provided with two elevating mechanisms 31a in the flange 32 so as to sandwich the support 30. The elevating mechanism 31a includes an actuator such as a motor therein, and a rod 31b is expanded or contracted by the driving force of the actuator to move the support 30 up and down. The elevating unit 31 moves the support 30 up and down by moving the two elevating mechanisms 31a up and down simultaneously. The elevating unit 31 moves the stage 2 up and down between the processing position illustrated in FIG. 1 by the solid line, and the transfer position illustrated by the two-dot chain line below the processing position where the wafer W may be transferred, and enables the wafer W to be carried in and out.

A bellows 26 is provided between the bottom surface of the processing container 1 and the flange 32 to partition an atmosphere in the processing container 1 from an outer air, and expand or contract according to a moving up and down operation of the stage 2.

Three wafer support pins 27 (only two are illustrated) are provided in the vicinity of the processing container 1 so as to protrude upward from an elevating plate 27a. The wafer support pins 27 move up and down by the elevating plate 27a with an elevating mechanism 28 provided below the processing container 1.

The wafer support pins 27 are configured to be inserted and penetrate through holes 2a provided in the stage 2 in the transfer position so as to be able to protrude and retreat from the upper surface of the stage 2. By moving the wafer support pins 27 up and down, delivery of the wafer W is performed between a transfer mechanism and the stage 2. A processing space 38 is formed between the stage 2 and the upper electrode 3 while the stage 2 is at the processing position.

An exhaust unit 4 exhausts the inside of the processing container 1. The exhaust unit 4 includes an exhaust pipe 41 connected to the exhaust port 13b and an exhaust mechanism 42 connected to the exhaust pipe 41 and including, for example, a vacuum pump or a pressure regulating valve. During a processing, the gas in the processing container 1 reaches the exhaust duct 13 via the slit 13a, and is exhausted from the exhaust duct 13 via the exhaust pipe 41 by the exhaust mechanism 42.

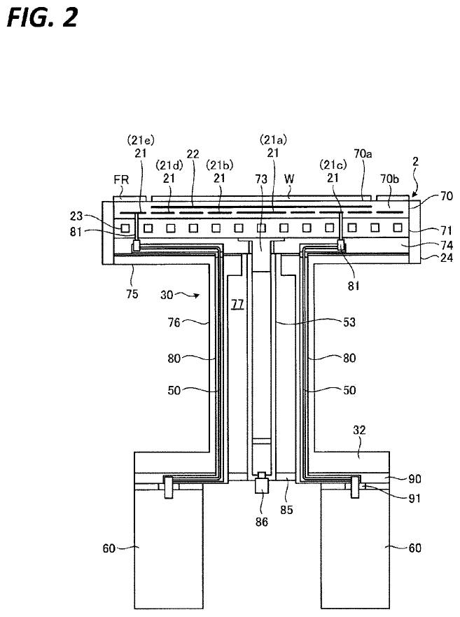

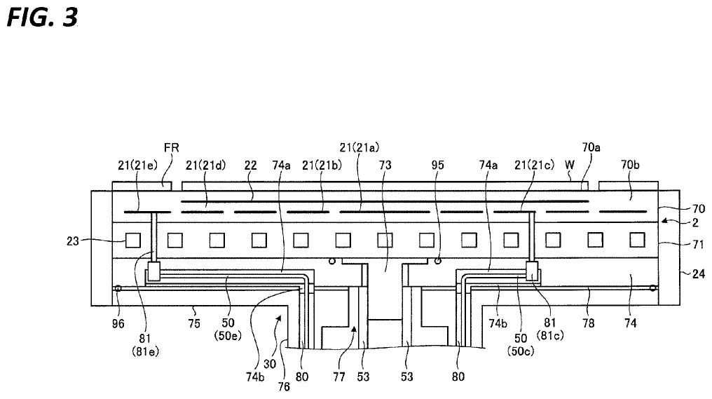

FIG. 2 is a cross-sectional view illustrating an example of a configuration of the stage and the support according to the embodiment. FIG. 3 is an enlarged view of a vicinity of the stage according to the embodiment. The stage 2 includes an electrostatic chuck 70 and a base 71.

The electrostatic chuck 70 is formed in a disk shape with a flat upper surface, and the upper surface serves as the placing surface 70a on which the wafer W is disposed. In the placing surface 70a, during the plasma processing, the wafer W is disposed in the center, and a focus ring FR is disposed around the wafer W. The focus ring FR is made of, for example, monocrystalline silicon.

The electrostatic chuck 70 includes the electrode 22 and an insulator 70b. The electrode 22 is provided inside the insulator 70b. As illustrated in FIG. 1, the electrode 22 is connected to the DC power source 62 via the wiring 51. The electrostatic chuck 70 adsorbs the wafer W by the Coulomb force by applying a DC voltage to the electrode 22. Further, in the electrostatic chuck 70, the heater 21 is provided inside the insulator 70b.

Here, in the electrostatic chuck 70 according to the embodiment, the placing surface 70a is divided into a plurality of zones, and the heater 21 is embedded in each zone, respectively, and the temperature of each zone may be controlled individually. For example, the electrostatic chuck 70 is divided into a circular zone and an annular zone from the center of the placing surface 70a toward the outer peripheral side in order, and the heater 21 is embedded in each zone. For example, in the electrostatic chuck 70, the region where the wafer W is disposed is divided into a central circular zone and three annular zones in order from the center, and heaters 21a to 21d are embedded. Further, in the electrostatic chuck 70, a heater 21e is embedded in the region where the focus ring FR is disposed as one zone. The heaters 21a to 21e are individually connected to five wirings 50 (50a to 50e) that supply power, respectively. In the embodiment, the placing surface 70a is divided into five zones and the heater 21 is provided in each zone to control the temperature. However, the number of zones is not limited to five, and may be two to four, or six or more.

The base 71 is disposed below the electrostatic chuck 70. The base 71 is formed in a flat plate-shaped having a size substantially the same as the electrostatic chuck 70, and supports the electrostatic chuck 70. The base 71 is made of a conductive metal, for example, aluminum having an anodized film formed on the surface thereof. The base 71 functions as a lower electrode.

The base 71 is connected to a power supply rod 73 that supplies a radio-frequency power. The power supply rod 73 is connected to the wiring 53. In the embodiment, the wiring 53 is configured as a cylindrical pipe having an air atmosphere inside. Further, the coolant flow path 23 is formed inside the base 71.

A dielectric portion 74 is disposed below the base 71. The dielectric portion 74 is formed in a flat plate-shaped having a size substantially the same as the base 71, and supports the base 71. The dielectric portion 74 is made of a dielectric material, for example, ceramics such as alumina or glass such as quartz.

The support 30 is disposed below the dielectric portion 74. The support 30 includes a flat plate-shaped flat plate 75 having a size substantially the same as the base 71 in the upper portion and a cylinder-shaped columnar portion 76 that supports the flat plate 75 in the lower portion. The support 30 is made of a conductive metal, for example, aluminum having an anodized film formed on the surface thereof.

A cover member 24 is disposed on the side surfaces of the stage 2, the dielectric portion 74, and the flat plate 75.

In the support 30, a hollow portion 77, which is hollow, is formed along an axis of the columnar portion 76. In the hollow portion 77 in the columnar portion 76, the wiring 53 is disposed at a distance from the inner wall surface of the columnar portion 76.

Further, in the support 30, a through hole 80 used for arrangement of various wirings or as various pipes is formed along the axis in the side wall of the columnar portion 76. Here, the stage 2 according to the embodiment requires the five wirings 50a to 50e for power supply to the heaters 21a to 21e, the wiring 51 for power supply to the electrode 22, the wiring 52 for the fiber thermometer, the pipe 55 for a heat transfer gas, and the pipes 56 and 57 for coolant circulation. As a result, ten through holes 80 are formed in the side wall of the columnar portion 76.

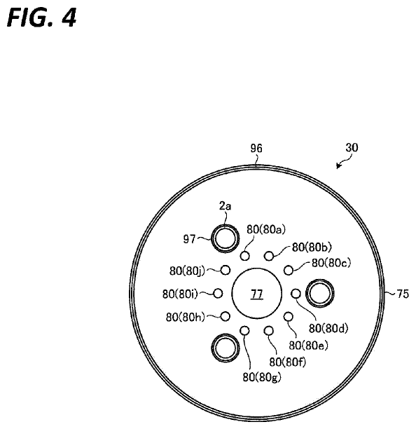

FIG. 4 is a top view illustrating an example of the configuration of the support according to the embodiment. FIG. 4 illustrates the top view of the support 30 viewed from the flat plate 75 side. In the flat plate 75 of the support 30, the circular hollow portion 77 is formed in the center. Further, in the flat plate 75 of the support 30, ten through holes 80a to 80j are formed around the hollow portion 77. Further, in the flat plate 75 of the support 30, the through holes 2a through which the above-described wafer support pins 27 pass are formed.

In the through holes 80a to 80j, the wirings 50a to 50e, 51, and 52 and the pipes 55, 56, and 57 are individually disposed. In the embodiment, the wirings 50a to 50e are disposed in the through holes 80a, 80d, 80f, 80h, and 80i, respectively. The pipes 56 and 57 are disposed in the through holes 80b and 80c, respectively. The wiring 52 is disposed in the through hole 80e. The wiring 51 is disposed in the through hole 80g. The pipe 55 is disposed in the through hole 80j.

In the stage 2, a power supply terminal 81 to the heater 21 is provided below the placing position of the heater 21. FIG. 3 illustrates a power supply terminal 81c connected to the heater 21c and a power supply terminal 81e connected to the heater 21e are illustrated.

The power supply terminal 81 of each heater 21 is individually connected to the wiring 50. FIG. 3 illustrates the wiring 50c that supplies power to the power supply terminal 81c and the wiring 50e that supplies power to the power supply terminal 81e.

Further, the stage 2 includes a power supply terminal (not illustrated) that supplies power to the electrode 22. The power supply terminal of the electrode 22 is connected to the wiring 51. Further, in the stage 2, a fiber thermometer (not illustrated) is provided at a predetermined position serving as a temperature measuring target. The fiber thermometer is connected to the wiring 52. Further, the stage 2 includes a through hole (not illustrated) communicated with the ejection port of a heat transfer gas. The through hole communicated with the ejection port is connected to the pipe 55. Further, the base 71 includes an opening (not illustrated) serving as one end and the other end of the coolant flow path 23 at the lower surface thereof. The opening at the one end of the coolant flow path 23 is connected to the pipe 56 and the opening on the other side is connected to the pipe 57.

In the dielectric portion 74, a recess 74a is formed in the lower surface along the respective placing paths of the respective wirings 50, 51, and 52, and the pipes 55, 56, and 57, and the respective placing paths of the respective wirings 50, 51, and 52, and the pipes 55, 56, and 57 are accommodated in the recess 74a. In the example in FIG. 3, the wiring 50c is accommodated in the recess 74a connecting the power supply terminal 81c and the through hole 80, and the wiring 50e is accommodated in the recess 74a connecting the power supply terminal 81e and the through hole 80. In the recess 74a, a cover 74b is provided in order to fix and protect the respective accommodated wirings 50, 51, and 52, and the pipes 55, 56, and 57.

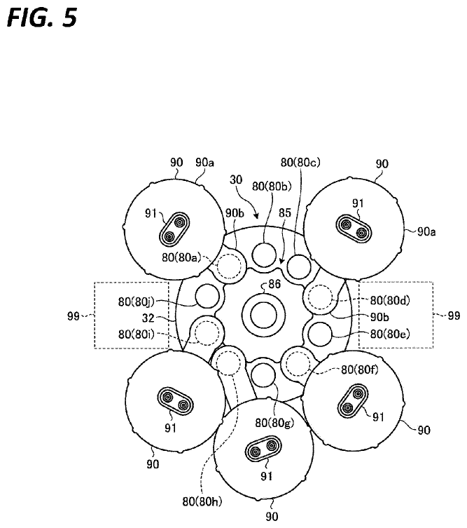

The wirings 50, 51, and 52, and the pipes 55, 56, and 57 reach the lower surface of the support 30 through the through hole 80, respectively. FIG. 5 is a bottom view illustrating an example of the configuration of the support according to the embodiment. FIG. 5 illustrates the bottom view of the support 30 viewed from the columnar portion 76 side. The hollow portion 77 formed in the columnar portion 76 reaches the lower surface. In the lower surface of the columnar portion 76, an insulating protective member 85 is provided to cover the hollow portion 77. The protective member 85 is provided with a power supply terminal 86. The wiring 53 is connected to the power supply terminal 86. The power supply terminal 86 is connected to the first radio-frequency power source 64 via a matcher 63 by a wiring (not illustrated), and a radio-frequency power having a predetermined frequency is supplied from the first radio-frequency power source 64.

Although the hollow portion 77 in the columnar portion 76 serves as an air atmospheric space filled with air, the protective member 85 is provided in order to suppress the exchange of the air with the outside.

As illustrated in FIG. 3, a gap 78 is formed between the flat plate 75 and the dielectric portion 74. For example, the flat plate 75 and the dielectric portion 74 are partially in contact with each other by a protrusion (not illustrated) formed on a facing surface of at least one of the flat plate 75 and the dielectric portion 74, and the gap 78 is formed in a portion other than the protrusion. The gap 78 may be several mm (e.g., 1 mm to 3 mm). The gap 78 serves as an air atmospheric space communicated with the hollow portion 77 and filled with air, and is formed in all circumferential directions of the facing surface.

In the stage 2, the dielectric portion 74, and the support 30, seals are provided in order to block the air in the hollow portion 77 and the gap 78 and keep the inside of the processing container 1 in a vacuum state. For example, in the dielectric portion 74, a seal 95 is provided around the power supply rod 73 in the surface facing the stage 2. Further, as illustrated in FIG. 4, in the support 30 and the flat plate 75, a seal 96 is provided along the edge of the surface facing the dielectric portion 74. Further, in the flat plate 75, a seal is individually provided so as to surround the through hole. For example, in the flat plate 75, a seal 97 is provided around each through hole 2a. Therefore, the leakage of the air in the gap 78 into the processing container 1 is prevented.

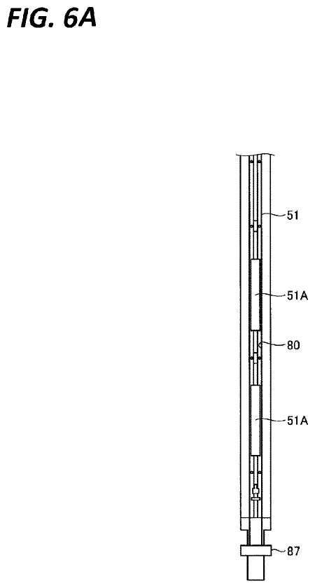

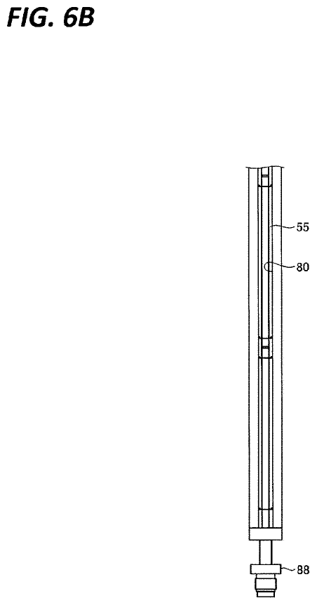

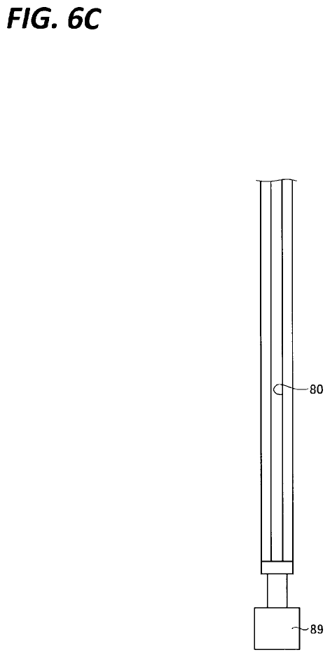

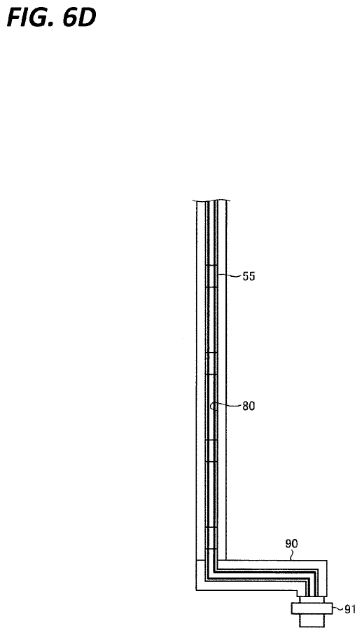

Next, the arrangement of the wiring in the through hole 80 will be described. FIG. 6A is a view illustrating an example of the arrangement of the wiring in the through hole according to the embodiment. FIG. 6A illustrates an example of the arrangement of the wiring 51 that supplies power to the electrode 22. The wiring 51 includes a noise filter 51A, is covered with an insulating member (not illustrated) such as Teflon (registered trademark) on its surroundings, and is disposed so as to be stationary in the through hole 80. In the lower portion of the through hole 80, a connection terminal 87 connected to the end portion of the wiring 51. The connection terminal 87 is connected to the DC power source 62 via a wiring (not illustrated).

FIG. 6B is a view illustrating an example of an arrangement of the wiring in the through hole according to the embodiment. FIG. 6B illustrates an example of the arrangement of the pipe 55 in the through hole 80. The pipe 55 is covered with an insulating member (not illustrated) on its surroundings, and is disposed so as to be stationary in the through hole 80. In the lower portion of the through hole 80, a connection terminal 88 is provided, and the connection terminal 88 is connected to the gas supply source 65 via a pipe (not illustrated).

FIG. 6C is a view illustrating an example of the arrangement of the wiring in the through hole according to the embodiment. FIG. 6C is a view illustrating an example of the arrangement of the pipes 56 and 57 through which the coolant flows in the through hole 80. The through hole 80 for the pipes 56 and 57 has the same configuration, and thus, descriptions will be made on the pipe 56. In the embodiment, the through hole 80 is used as the pipe 56 with respect to the support 30. In the lower portion of the through hole 80, a connection terminal 89 is provided, and the connection terminal 89 is connected to the coolant unit 66 via a pipe (not illustrated). The two connection terminals 89 for the pipes 56 and 57 are equipotential in the lower portion of the through hole 80.

FIG. 6D is a view illustrating an example of the arrangement of the wiring in the through hole according to the embodiment. FIG. 6D is a view illustrating an example of the arrangement of the wiring 50 that supplies power to the heater 21 in the through hole 80. In the embodiment, the wiring 50 that supplies power to the heater 21 is a two-wiring power supply by two conducting wires, and an insulating member covers the space between the two conducting wires and the surroundings thereof. The wiring 50 is covered with an insulating member (not illustrated) on its surroundings, and is disposed so as to be stationary in the through hole 80. In the lower portion of the through hole 80, a connector 90 is provided. As illustrated in FIG. 2, the connector 90 offsets the wiring 50 to the outer peripheral side in order to secure a space for disposing the filter 60, and a connection terminal 91 serving as the terminal of the wiring 50 is provided in the lower surface.

As illustrated in FIG. 5, in the connector 90, a disc portion 90a is formed in a disc shape, and a projection 90b protruding in the radial direction is provided on a part of the circumference of the disc portion 90a. In the center of the disc portion 90a, the connection terminal 91 is provided.

The connector 90 is disposed in each of the through holes 80 through which the wiring 50 that supplies power to the heater 21 passes. The connector 90 is disposed such that the projection 90b covers the through hole 80, and the disc portion 90a faces the outer peripheral side of the support 30.

Here, in the embodiment, the through holes 80 through which the wiring 50 passes are determined such that the connectors 90 are substantially evenly disposed around the lower surface of the support 30. In the embodiment, the wirings 50a to 50e are disposed in the through holes 80a, 80d, 80f, 80h, and 80i, respectively. Therefore, in the example in FIG. 5, two connectors 90 are disposed in the upper side and three connectors 90 are disposed in the lower side. Further, in the example in FIG. 5, the two connectors 90 are disposed at a distance from each other in the upper side so that the respective connectors 90 are substantially evenly disposed on the top, bottom, left, and right. Further, some connectors 90 are disposed at a distance from each other symmetrically with respect to the support 30 around the lower surface of the support 30, in order to secure a space for disposing the elevating mechanism 31a. In the example in FIG. 5, a space 99 illustrated by a broken line is secured symmetrically with respect to the support 30. In the space 99, the above-described elevating mechanism 31a is disposed, respectively.

In the lower end of the support 30, the flange 32 is provided. The connectors 90 are fixed to the flange 32, respectively. The connection terminal 91 of each connector 90 is connected to the filter 60, respectively. The filter 60 is fixed to the flange 32 so as to move up and down integrally with the support 30. The filter 60 is connected to the heater power source 61 via a wiring (not illustrated). The support 30 is grounded at the lower portion of the flange 32 or the columnar portion 76 via a wiring (not illustrated), and has a ground potential. The filter 60 is communicated and equipotential with the support 30. For example, the case of the filter 60 is electrically connected to the flange 32 to have a ground potential.

Reference is made back to FIG. 1. The operation of the plasma processing apparatus 100 configured as described above is generally controlled by the controller 6. The controller 6 is, for example, a computer, and includes, for example, a central processing unit (CPU), a random access memory (RAM), a read only memory (ROM), and an auxiliary storage device. The CPU is operated based on a program stored in the ROM or the auxiliary storage device, or a process condition for a plasma processing, and controls the operation of the entire device. For example, the controller 6 controls the supply operation of the various gases from the gas supply mechanism 5, the moving up and down operation of the elevating unit 31, the exhaust operation in the processing container 1 by the exhaust mechanism 42, and the supply power from the first radio-frequency power source 64 and the second radio-frequency power source 46. The computer readable program required for the control may be stored in a storage medium. The storage medium includes, for example, a flexible disk, a compact disk (CD), a CD-ROM, a hard disk, a flash memory, or a DVD. Further, the controller 6 may be provided inside the plasma processing apparatus 100, or may be provided outside. When the controller 6 is provided outside, the controller 6 may control the plasma processing apparatus 100 by, for example, a wired or a wireless communication means.

Next, a flow of the plasma processing executed by the plasma processing apparatus 100 by the control of the controller 6 will be briefly described. The plasma processing apparatus 100 depresses the inside of the processing container 1 to a vacuum atmosphere by the exhaust mechanism 42. When carrying in the wafer W, the plasma processing apparatus 100 lowers the stage 2 to the transport position of the wafer W, and opens the gate valve 12. The wafer W is carried onto the stage 2 by the transfer mechanism through the carry-in/out port 11. The plasma processing apparatus 100 closes the gate valve 12, and raise the stage 2 to the processing position.

After the pressure in the processing container 1 is adjusted, the plasma processing apparatus 100 generates a plasma by applying a radio-frequency having a predetermined frequency to the upper electrode 3 and the stage 2 while supplying the various gases used in the plasma processing from the upper electrode 3 into the processing container 1.

However, as described above, in the plasma processing apparatus 100, the radio-frequency noise is generated as the plasma is generated. For example, in the wiring 50 that supplies power to the heater 21, noise may be propagated by the radio-frequency power applied during the plasma processing. When the noise propagated in the wiring 50 enters the heater power source 61, the operation or performance of the heater power source 61 may be impaired.

Therefore, in the plasma processing apparatus 100, the noise propagated in the wiring 50 is suppressed to a sufficient level by the filter 60. In the filter 60, an air core coil is provided, and the winding gap of the air core coil is adjusted so that a parallel resonance frequency corresponding to the noise frequency may be obtained.

Further, in the plasma processing apparatus 100, the filter 60 is fixed to the support 30, and when the stage 2 is moved up and down, the support 30 and the filter 50 are moved up and down integrally. Therefore, in the plasma processing apparatus 100, even when the stage 2 is moved up and down, the wiring 50 is not moved by the moving up and down, and further, the wiring length of the wiring 50 is not changed, and thus, the impedance of the wiring 50 is not changed. As a result, in the plasma processing apparatus 100, even when the stage 2 is moved up and down, the noise in the wiring 50 may be suppressed to a sufficient level by the filter 60.

In the plasma processing apparatus 100, noise or discharge is likely to occur when the frequency of the radio-frequency power applied during the plasma processing is MHz or higher. Therefore, in the plasma processing apparatus 100, the wirings 50, 51, and 52, and the pipes 55, 56, and 57 are accommodated in the through holes 80 formed in the conductive support 30. The conductive support 30 acts as a shield. As a result, in the plasma processing apparatus 100, it is possible to suppress the noise due to the radio-frequency power from entering the wirings 50, 51, and 52, and the pipes 55, 56, and 57.

Further, in the plasma processing apparatus 100, the hollow portion 77 with an air atmosphere is formed in the support 30, and the wiring 53 through which a radio-frequency power flows is disposed at a distance from the inner wall surface of the columnar portion 76. Therefore, in the plasma processing apparatus 100, it is possible to suppress the occurrence of discharge at the surroundings even when the radio-frequency power flows through the wiring 53. Further, the wirings 50, 51, and 52, and the pipes 55, 56, and 57 are accommodated in the through holes 80 formed in the conductive support 30. The conductive support 30 acts as a shield. As a result, when the radio-frequency power is supplied to the wiring 53, it is possible to suppress the noise due to the radio-frequency power from entering the wirings 50, 51, and 52, and the pipes 55, 56, and 57.

Further, in the plasma processing apparatus 100, the gap 78 with an air atmosphere is formed between the flat plate 75 and the dielectric portion 74. Therefore, in the plasma processing apparatus 100, it is possible to suppress the occurrence of abnormal discharge due to, for example, the noise occurred as a plasma is generated in the stage 2, and to suppress the leakage of the noise to the outside through the support 30.

As described above, the plasma processing apparatus 100 according to the present embodiment includes the support 30, the filter 60, and the elevating unit 31. The support 30 supports the stage 2 on which the wafer W serving as a plasma processing target is disposed, and the wiring 50 used for the plasma processing is disposed in the support 30. The filter 60 is connected to the end portion of the wiring 50, and attenuates the noise generated in the wiring 50. The elevating unit 31 moves the support 30 and the filter 60 up and down integrally. As described above, by moving the support 30 and the filter 60 up and down integrally, the wiring 50 does not move due to the moving up and down, and the impedance of the wiring 50 is not changed. Therefore, in the plasma processing apparatus 100, even when the stage 2 is moved up and down via the support 30 by the elevating unit 31, it is possible to suppress the noise propagated through the wiring 50 by the filter 60.

Further, in the plasma processing apparatus 100 according to the present embodiment, the filter 60 is fixed to the support 30. Therefore, in the plasma processing apparatus 100, the filter 60 and the support 30 may be moved up and down integrally. As a result, in the plasma processing apparatus 100, even when the stage 2 is moved up and down via the support 30 by the elevating unit 31, it is possible to suppress the noise propagated through the wiring 50 by the filter 60.

Further, in the plasma processing apparatus 100 according to the embodiment, the support 30 has conductivity, has a ground potential, and has the through hole 80 accommodating the wiring 50 therein. The filter 60 is communicated and equipotential with the support 30. As a result, in the plasma processing apparatus 100, the support 30 acts as a shield, and thus, it is possible to suppress the noise due to the radio-frequency power from entering the wiring 50.

Further, in the plasma processing apparatus 100 according to the embodiment, the wiring 50 is covered with an insulating member on its surroundings, and is disposed so as to be stationary in the through hole 80. Therefore, in the plasma processing apparatus 100, even when the stage 2 is moved up and down, the wiring 50 is not moved in the through hole 80, and the impedance of the wiring 50 is not changed. As a result, in the plasma processing apparatus 100, the noise in the wiring 50 may be suppressed by the filter 60.

Further, in the plasma processing apparatus 100 according to the embodiment, the stage 2 includes the heater 21 that generates heat by supplying power. The wiring 50 serves as a power supply wiring that supplies power to the heater 21. Therefore, in the plasma processing apparatus 100, it is possible to sufficiently suppress the noise propagated through the power supply wiring to the heater 21. As a result, in the plasma processing apparatus 100, it is possible to suppress the noise from entering the heater power source 61, and to suppress the operation or performance of the heater power source 61 from being impaired.

Further, the plasma processing apparatus 100 according to the present embodiment further includes the dielectric portion 74 made of a dielectric material between the stage 2 and the support 30. The gap 78 with an air atmosphere is formed between the support 30 and the dielectric portion 74, and the seal 96 is provided along the edge of the surface facing the dielectric material. Therefore, in the plasma processing apparatus 100, it is possible to suppress the occurrence of discharge in the gap 78 due to, for example, the noise generated by the radio-frequency power.

Further, in the plasma processing apparatus 100 according to the embodiment, the support 30 includes the flat plate-shaped flat plate 75 facing the stage 2, and the columnar portion 76 that supports the flat plate 75, has a cylindrical shape, and has the hollow portion 77 with an air atmosphere along the axis of the cylinder. In the plasma processing apparatus 100, the wiring 53 that supplies a radio-frequency power to the stage 2 is disposed in the hollow portion 77 at a distance from the inner wall surface of the columnar portion 76. Therefore, in the plasma processing apparatus 100, it is possible to suppress the occurrence of discharge at the surroundings of the wiring 53 even when the radio-frequency power flows through the wiring 53.

Further, in the plasma processing apparatus 100 according to the embodiment, the support 30 includes a plurality of wirings 50. A plurality of filters 60 is provided corresponding to the plurality of wirings 50, and is fixed to the lower surface of the flange 32 provided below the support 30 so as to be evenly disposed in the circumferential direction. Therefore, in the plasma processing apparatus 100, the plurality of filters 60 may be disposed in the flange 32 in a well-balanced manner, and the stability when moving the support 30 up and down may be improved.

In the above, although the embodiments have been described in the above, it should be considered that the embodiments disclosed in here are exemplary and not restrictive in all aspects. In practice, the embodiments described above may be implemented in various forms. Further, the above-described embodiments may be omitted, replaced, or changed in various forms without departing from the scope of claims and the gist thereof.

For example, in the embodiments, the case where the processing target is a semiconductor wafer is described as an example, but the present disclosure is not limited thereto. The processing target may be other substrates such as a glass substrate.

Further, in the embodiments, the plasma processing apparatus 100 that performs film formation is described as an example, but the present disclosure is not limited thereto. Any plasma processing apparatus 100 may be used as long as the stage 2 is moved up and down to perform a plasma processing.

Further, in the embodiments, the frequency of the radio-frequency power applied to the upper electrode 3 and the stage 2 is set to 13.56 MHz, but the present disclosure is not limited thereto. The frequency of the radio-frequency power may be, for example, 2 MHz to 60 MHz, or may be a VHF frequency band.

Further, in the embodiments, the case where the temperature of the stage 2 is measured by a fiber thermometer is described as an example, but the present disclosure is not limited thereto. For example, a thermocouple may be provided in the stage 2 and the temperature may be measured from the signal of the thermocouple via the wiring 51. Since noise is propagated in the wiring 51, similar to the wiring 50, the wiring 51 includes the filter 60 at the end portion and the filter 60 is fixed to the support 30.

### DESCRIPTION OF SYMBOLS

1: processing container
2: stage
21, 21a to 21e: heater
22: electrode
31: elevating unit
31a: elevating mechanism
32: flange
50, 50a to 50e: wiring
51: wiring
52: wiring
53: wiring
55: pipe
56: pipe
57: pipe
60: filter
61: heater power source
62: DC power source
63: matcher
64: first radio-frequency power source
65: gas supply source
66: coolant unit
70: electrostatic chuck
71: base
74: dielectric portion
75: flat plate
76: columnar portion
77: hollow portion
78: gap
80, 80a to 80j: through hole
81: power supply terminal
86: power supply terminal
87: connection terminal
88: connection terminal
89: connection terminal
90: connector
91: connection terminal
95: seal
96: seal
97: seal
100: plasma processing apparatus
W: wafer

What is claimed is:

1. A plasma processing apparatus comprising:
a support provided with a wiring used for a plasma processing and configured to support a stage on which a workpiece serving as a plasma processing target is disposed;
a filter connected to an end portion of the wiring and configured to attenuate noise propagated through the wiring; and
a lift configured to move the support and the filter up and down integrally.

2. The plasma processing apparatus according to claim 1, wherein the filter is fixed to the support.

3. The plasma processing apparatus according to claim 1, wherein the support has conductivity and is in a ground potential, and includes a through hole that accommodates the wiring therein, and
the filter is electrically connected to the support and is equipotential with the support.

4. The plasma processing apparatus according to claim 3, wherein the wiring is surrounded by an insulating member and disposed to be fixed in the through hole.

5. The plasma processing apparatus according to claim 1, wherein the stage includes a heater that generates heat by supplying power, and
the wiring serves as a power supply wiring that supplies power to the heater.

6. The plasma processing apparatus according to claim 1, further comprising:
a dielectric portion made of a dielectric material between the stage and the support,
wherein a gap with an air atmosphere is formed between the support and the dielectric portion, and a seal is provided along an edge of a surface facing the dielectric material.

7. The plasma processing apparatus according to claim 1, wherein the support includes a flat plate facing the stage, and a columnar portion formed in a cylindrical shape that supports the flat plate and has a hollow with an air atmosphere along an axis of the cylinder, and
a power supply wiring that supplies a radio-frequency power to the stage is disposed in the hollow at a distance from an inner wall surface of the columnar portion.

8. The plasma processing apparatus according to claim 1, wherein the support includes a plurality of wirings, and
a plurality of filters is provided corresponding to the plurality of wirings, and fixed to a lower surface of a flange provided below the support to be evenly disposed in a circumferential direction.
